(19) United States
(12) Patent Application Publication
(10) Pub. No.: US 2025/0309204 A1
(43) Pub. Date: Oct. 2, 2025

(54) VERTICAL MULTI-FUNCTION POWER DELIVERY DEVICES

(71) Applicant: NVIDIA CORPORATION, Santa Clara, CA (US)

(72) Inventors: Wenjie ZHENG, Shenzhen (CN); Ziyuan ZHENG, Shenzhen (CN); Sien CHEN, Shenzhen (CN); Lin DENG, Shenzhen (CN); Siqi LI, Shenzhen (CN); Yu ZHAO, Shenzhen (CN)

(21) Appl. No.: 18/800,991

(22) Filed: Aug. 12, 2024

Related U.S. Application Data
(60) Provisional application No. 63/570,059, filed on Mar. 26, 2024.

(51) Int. Cl. H01L 25/16; H01L 23/00; H01L 23/538; H01L 29/78; H05K 1/18

(52) U.S. Cl. CPC H01L 25/16; H01L 24/32; H05K 1/181; H10D 1/20; H01L 23/538; H01L 2224/32245; H05K 2201/10378; H10D 30/60

(57) ABSTRACT

One embodiment of a power delivery device includes an inductor and one or more chips that are mounted on top of the inductor. One embodiment of a graphics card includes a graphics processing unit (GPU) mounted on top of a first side of a circuit board, and one or more power delivery devices mounted on top of a second side of the circuit board. Each power delivery device included in the one or more power delivery devices includes an inductor and one or more chips disposed on top of the inductor.

### CROSS-REFERENCE TO RELATED APPLICATIONS

This application claims benefit of U.S. Provisional patent application titled “VERTICAL MULTI-FUNCTION N-IN-ONE INDUCTOR,” filed Mar. 26, 2024 and having Ser. No. 63/570,059. The subject matter of this related application is hereby incorporated herein by reference.

### BACKGROUND

### Field of the Various Embodiments

Various embodiments relate generally to computer processors and electronics and power delivery systems and, more specifically, to vertical multi-function power delivery devices.

### DESCRIPTION OF THE RELATED ART

Processors include electronic circuitry that can execute the instructions of computer programs and perform other operations, such as operations on external data sources, operations to control output devices, among other things. Different types of processors having various architectures, including central processing units (CPUs) with one or multiple cores and specialized processors such as graphics processing units (GPUs), have been developed for different purposes.

One conventional approach for delivering power to a processor is referred to as “flattened” power delivery. In flattened power delivery, power phases are placed around a processer in order to deliver power to the processor while regulating the voltage being supplied to the processor. For example, each power phase can include one or more metal-oxide-semiconductor field-effect transistors (MOSFETs) that convert the source voltage (e.g., 12V) of an electrical source into a core voltage that is then used to operate the processor.

One drawback of flattened power delivery is that the sizes of conventional power phases are large relative to the sizes of processors. Consequently, oftentimes, only a limited number of power phases can be placed around a given processor. The given processor is then constrained to consuming only the power that the limited number of power phases can provide. Accordingly, more complex processors that consume large amounts of power, such as GPUs used in the training of artificial intelligence (AI) models, can be difficult to implement and deploy using flattened power delivery.

Another drawback of flattened power delivery is that processor packages are increasing in size to provide greater computing performance. For example, GPU packages are becoming increasingly larger so that more complex execution circuitry and more high-bandwidth memory (HBM) sites can be placed within the GPU packages. Larger processor packages typically increase the distances between the power phases and the processor core power rails that draw power from the power phases. The increased distances can result in increased power loss and, accordingly, oftentimes cause decreases in power supply efficiency with which electrical energy provided by the power phases is converted to useful work by the processor.

As the foregoing illustrates, what is needed in the art are more effective techniques for delivering power to processors within computer systems.

### SUMMARY

One embodiment of the present disclosure sets forth a power delivery device. The power delivery device includes an inductor. The power delivery device further includes one or more chips that are mounted on top of the inductor.

Another embodiment of the present disclosure sets forth a graphics card. The graphics card includes a circuit board. The graphics card further includes a graphics processing unit (GPU) mounted on top of a first side of the circuit board. In addition, the graphics card includes one or more power delivery devices mounted on top of a second side of the circuit board. Each power delivery device included in the one or more power delivery devices comprises an inductor and one or more chips disposed on top of the inductor.

Another embodiment of the present disclosure sets forth a computer system. The computer system includes a processor. The computer system further includes one or more power delivery devices that delivery power to the processor. Each power delivery device included in the one or more power delivery devices includes an inductor on top of which one or more chips are mounted.

One technical advantage of the disclosed techniques relative to the prior art is that the disclosed power delivery devices can be smaller in size (in the x-y plane and in height) relative to the power phases used in conventional power delivery approaches. Accordingly, a relatively large number of the disclosed power delivery devices can be placed underneath a processor to deliver power, which permits a higher amount of power to be delivered. In addition, the disclosed power delivery devices can provide improved power supply efficiency, including higher power density, relative to conventional power delivery approaches. These technical advantages provide one or more technological improvements over prior art approaches.

### BRIEF DESCRIPTION OF THE DRAWINGS

So that the manner in which the features of the various embodiments recited herein can be understood in detail, a more particular description of the inventive concepts, briefly summarized herein, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a computing system configured to implement one or more aspects of the various embodiments;

FIG. 2 is a block diagram of a parallel processing unit (PPU) included in the parallel processing subsystem of FIG. 1, according to various embodiments;

FIG. 3 is a block diagram of a general processing cluster (GPC) included in the parallel processing unit of FIG. 2, according to various embodiments;

FIG. 4 is a schematic diagram illustrating a power delivery device, according to various embodiments;

FIG. 5 is a schematic diagram illustrating a top-down view of the power delivery device of FIG. 4, according to various embodiments;

FIG. 6A is a schematic diagram illustrating a top-down view of an inductor, according to various embodiments;

FIG. 6B is a schematic diagram illustrating a bottom-up view of the inductor of FIG. 6A, according to various embodiments;

FIG. 7A is a schematic diagram illustrating a top-down view of an inductor, according to various other embodiments;

FIG. 7B is a schematic diagram illustrating a bottom-up view of the inductor of FIG. 7A, according to various other embodiments;

FIG. 8 is a schematic diagram illustrating a top-down view of a power delivery device, according to various other embodiments;

FIG. 9 is a schematic diagram illustrating an exemplar footprint on top of which a DrMOS can be mounted on an inductor, according to various embodiments;

FIG. 10 is a schematic diagram illustrating a power delivery device, according to various other embodiments;

FIGS. 11A and 11B are schematic diagrams illustrating a power delivery device, according to various other embodiments; and

FIG. 12 is a schematic diagram illustrating a bottom-up view of a graphics processing unit and associated power delivery devices, according to various embodiments.

### DETAILED DESCRIPTION

In the following description, numerous specific details are set forth to provide a more thorough understanding of the various embodiments. However, it will be apparent to one skilled in the art that the inventive concepts can be practiced without one or more of these specific details.

### System Overview

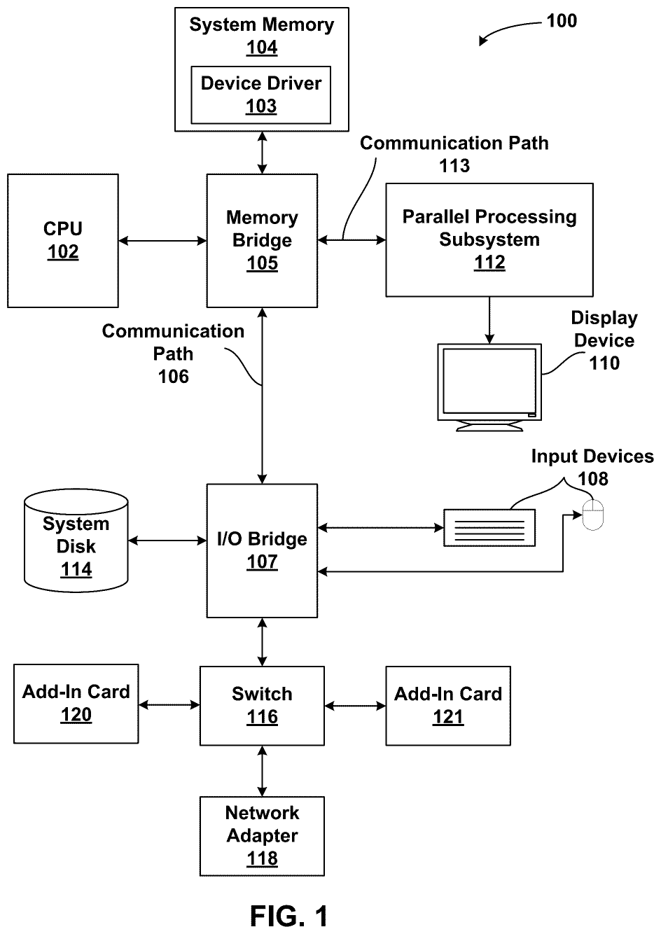

FIG. 1 is a block diagram of a computing system 100 configured to implement one or more aspects of the various embodiments. As shown, computing system 100 includes, without limitation, a central processing unit (CPU) 102 and a system memory 104 coupled to a parallel processing subsystem 112 via a memory bridge 105 and/or a communication path 113. Memory bridge 105 is further coupled to an I/O (input/output) bridge 107 via a communication path 106, and/or I/O bridge 107 is, in turn, coupled to a switch 116.

In operation, I/O bridge 107 is configured to receive user input information from input devices 108, such as a keyboard or a mouse, and/or forward the input information to CPU 102 for processing via communication path 106 and/or memory bridge 105. In some examples, without limitation, input devices 108 are employed to verify the identities of one or more users in order to permit access of computing system 100 to authorized users and/or deny access of computing system 100 to unauthorized users. Switch 116 is configured to provide connections between I/O bridge 107 and/or other components of the computing system 100, such as a network adapter 118 and/or various add-in cards 120 and 121. In some examples, without limitation, network adapter 118 serves as the primary or exclusive input device to receive input data for processing via the disclosed techniques.

As also shown, I/O bridge 107 is coupled to a system disk 114 that can be configured to store content and/or applications and/or data for use by CPU 102 and/or parallel processing subsystem 112. As a general matter, system disk 114 provides non-volatile storage for applications and/or data and can include fixed or removable hard disk drives, flash memory devices, and/or CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and/or the like, can be connected to I/O bridge 107 as well.

In various embodiments, memory bridge 105 can be a Northbridge chip, and/or I/O bridge 107 can be a Southbridge chip. In addition, communication paths 106 and/or 113, as well as other communication paths within computing system 100, can be implemented using any technically suitable protocols, including, without limitation, Peripheral Component Interconnect Express (PCIe), HyperTransport, or any other bus or point-to-point communication protocol known in the art.

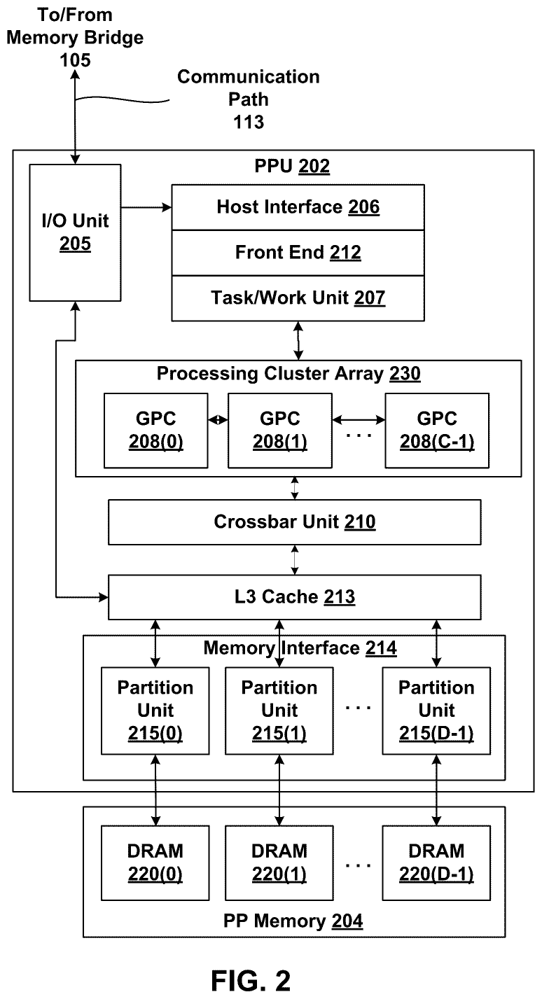

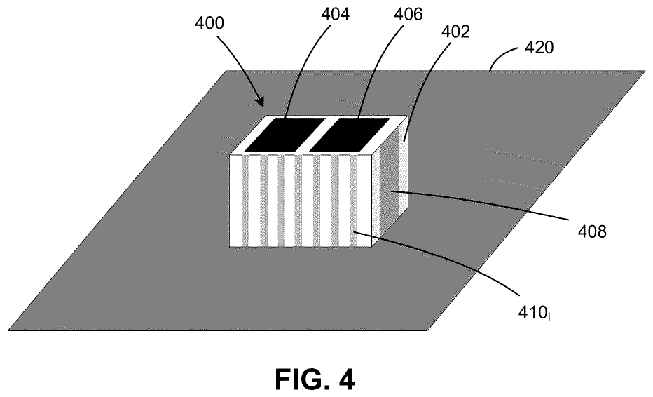

In some embodiments, parallel processing subsystem 112 comprises a graphics subsystem that delivers pixels to a display device 110 that can be any conventional cathode ray tube, liquid crystal display, light-emitting diode display, or the like. In such embodiments, the parallel processing subsystem 112 incorporates circuitry optimized for graphics and/or video processing, including, for example, without limitation, video output circuitry. As described in greater detail herein in FIG. 2, such circuitry can be incorporated across one or more parallels included within parallel processing subsystem 112. Parallel processing subsystem 112 includes one or more processing units that can execute instructions such as a central processing unit (CPU), a parallel processing unit (PPU) of FIGS. 2-4, a graphics processing unit (GPU), a direct memory access (DMA) unit, an intelligence processing unit (IPU), neural processing unit (NAU), tensor processing unit (TPU), neural network processor (NNP), a data processing unit (DPU), a vision processing unit (VPU), an application specific integrated circuit (ASIC), a field-programmable gate array (FPGA), and/or the like. In some embodiments, one or more of the power delivery devices described in greater detail below in conjunction with FIGS. 4-12 can be used to deliver power to one or more processing units included in the parallel processing subsystem 112.

In some embodiments, parallel processing subsystem 112 includes two processors, referred to herein as a primary processor (normally a CPU) and/or a secondary processor. Typically, the primary processor is a CPU and/or the secondary processor is a GPU. Additionally or alternatively, each of the primary processor and/or the secondary processor can be any one or more of the types of parallels disclosed herein, in any technically feasible combination. The secondary processor receives secure commands from the primary processor via a communication path that is not secured. The secondary processor accesses a memory and/or other storage system, such as system memory 104, Compute eXpress Link (CXL) memory expanders, memory managed disk storage, on-chip memory, and/or the like. The secondary processor accesses this memory and/or other storage system across an insecure connection. The primary processor and/or the secondary processor can communicate with one another via a GPU-to-GPU communications channel, such as Nvidia Link (NVLink). Further, the primary processor and/or the secondary processor can communicate with one another via network adapter 118. In general, the distinction between an insecure communication path and/or a secure communication path is application dependent. A particular application program generally considers communications within a die or package to be secure. Communications of unencrypted data over a standard communications channel, such as PCIe, are considered to be unsecure.

In some embodiments, the parallel processing subsystem 112 incorporates circuitry optimized for general purpose and/or compute processing. Again, such circuitry can be incorporated across one or more parallel processing units included within parallel processing subsystem 112 that are configured to perform such general purpose and/or compute operations. In yet other embodiments, the one or more parallel processing units included within parallel processing subsystem 112 can be configured to perform graphics processing, general purpose processing, and/or compute processing operations. System memory 104 includes at least one device driver 103 configured to manage the processing operations of the one or more parallels within parallel processing subsystem 112.

In various embodiments, parallel processing subsystem 112 can be integrated with one or more of the other elements of FIG. 1 to form a single system. For example, without limitation, parallel processing subsystem 112 can be integrated with CPU 102 and/or other connection circuitry on a single chip to form a system on chip (SoC).

It will be appreciated that the system shown herein is illustrative and that variations and/or modifications are possible. The connection topology, including the number and/or arrangement of bridges, the number of CPUs 102, and/or the number of parallel processing subsystems 112, can be modified as desired. For example, without limitation, in some embodiments, system memory 104 can be connected to CPU 102 directly rather than through memory bridge 105, and/or other devices would communicate with system memory 104 via memory bridge 105 and/or CPU 102. In other alternative topologies, parallel processing subsystem 112 can be connected to I/O bridge 107 or directly to CPU 102, rather than to memory bridge 105. In still other embodiments, I/O bridge 107 and/or memory bridge 105 can be integrated into a single chip instead of existing as one or more discrete devices. Lastly, in certain embodiments, one or more components shown in FIG. 1 can not be present. For example, without limitation, switch 116 can be eliminated, and/or network adapter 118 and/or add-in cards 120, 121 would connect directly to I/O bridge 107.

FIG. 2 is a block diagram of a parallel processing unit (PPU) 202 included in the parallel processing subsystem 112 of FIG. 1, according to various embodiments. Although FIG. 2 depicts one PPU 202, as indicated herein, parallel processing subsystem 112 can include any number of PPUs 202. Further, the PPU 202 of FIG. 2 is one non-limiting example of a parallel included in parallel processing subsystem 112 of FIG. 1. Alternative parallels include, without limitation, CPUs, GPUs, DMA units, IPUs, NPUs, TPUs, NNPs, DPUs, VPUs, ASICs, FPGAs, and/or the like. The techniques disclosed in FIGS. 2-4 with respect to PPU 202 apply equally to any type of parallel(s) included within parallel processing subsystem 112, in any combination. As shown, PPU 202 is coupled to a local parallel processing (PP) memory 204. PPU 202 and/or PP memory 204 can be implemented using one or more integrated circuit devices, such as programmable processors, application specific integrated circuits (ASICs), or memory devices, or in any other technically feasible fashion.

In some embodiments, PPU 202 comprises a graphics processing unit (GPU) that can be configured to implement a graphics rendering pipeline to perform various operations related to generating pixel data based on graphics data supplied by CPU 102 and/or system memory 104. When processing graphics data, PP memory 204 can be used as graphics memory that stores one or more conventional frame buffers and, if needed, one or more other render targets as well. Among other things, PP memory 204 can be used to store and/or update pixel data and/or deliver final pixel data or display frames to display device 110 for display. In some embodiments, PPU 202 also can be configured for general-purpose processing and/or compute operations.

In operation, CPU 102 is the master processor of computing system 100, controlling and/or coordinating operations of other system components. In particular, CPU 102 issues commands that control the operation of PPU 202. In some embodiments, CPU 102 writes a stream of commands for PPU 202 to a data structure (not explicitly shown in either FIG. 1 or FIG. 2) that can be located in system memory 104, PP memory 204, or another storage location accessible to both CPU 102 and/or PPU 202. Additionally or alternatively, processors and/or processing units other than CPU 102 can write one or more streams of commands for PPU 202 to a data structure. A pointer to the data structure is written to a pushbuffer to initiate processing of the stream of commands in the data structure. The PPU 202 reads command streams from the pushbuffer and/or then executes commands asynchronously relative to the operation of CPU 102. In embodiments where multiple pushbuffers are generated, execution priorities can be specified for each pushbuffer by an application program via device driver 103 to control scheduling of the different pushbuffers.

As also shown, PPU 202 includes an I/O (input/output) unit 205 that communicates with the rest of computing system 100 via the communication path 113 and/or memory bridge 105. I/O unit 205 generates packets (or other signals) for transmission on communication path 113 and/or also receives all incoming packets (or other signals) from communication path 113, directing the incoming packets to appropriate components of PPU 202. For example, without limitation, commands related to processing tasks can be directed to a host interface 206, while commands related to memory operations (e.g., reading from or writing to PP memory 204) can be directed to a crossbar unit 210. Host interface 206 reads each pushbuffer and/or transmits the command stream stored in the pushbuffer to a front end 212.

As mentioned herein in conjunction with FIG. 1, the connection of PPU 202 to the rest of computing system 100 can be varied. In some embodiments, parallel processing subsystem 112, which includes at least one PPU 202, is implemented as an add-in card that can be inserted into an expansion slot of computing system 100. In other embodiments, PPU 202 can be integrated on a single chip with a bus bridge, such as memory bridge 105 or I/O bridge 107. Again, in still other embodiments, some or all of the elements of PPU 202 can be included along with CPU 102 in a single integrated circuit or system of chip (SoC).

In operation, front end 212 transmits processing tasks received from host interface 206 to a work distribution unit (not shown) within task/work unit 207. The work distribution unit receives pointers to processing tasks that are encoded as task metadata (TMD) and/or stored in memory. The pointers to TMDs are included in a command stream that is stored as a pushbuffer and received by the front end 212 from the host interface 206. Processing tasks that can be encoded as TMDs include indices associated with the data to be processed as well as state parameters and/or commands that define how the data is to be processed. For example, without limitation, the state parameters and/or commands can define the program to be executed on the data. The task/work unit 207 receives tasks from the front end 212 and/or ensures that GPCs 208 are configured to a valid state before the processing task specified by each one of the TMDs is initiated. A priority can be specified for each TMD that is used to schedule the execution of the processing task. Processing tasks also can be received from the processing cluster array 230. Optionally, the TMD can include a parameter that controls whether the TMD is added to the head or the tail of a list of processing tasks (or to a list of pointers to the processing tasks), thereby providing another level of control over execution priority.

PPU 202 advantageously implements a highly parallel processing architecture based on a processing cluster array 230 that includes a set of C general processing clusters (GPCs) 208, where C≥1. Each GPC 208 is capable of executing a large number (e.g., hundreds or thousands) of threads concurrently, where each thread is an instance of a program. In various applications, different GPCs 208 can be allocated for processing different types of programs or for performing different types of computations. The allocation of GPCs 208 can vary depending on the workload arising for each type of program or computation. As will be described in more detail herein, one or more GPCs 208 can concurrently execute threads in a cooperative thread array (CTA) that cooperate and share data to perform collective computations.

In the illustrated example of FIG. 2, PPU 202 further includes a level three (L3) cache memory, or L3 cache, 213. As will be described in more detail herein, the L3 cache 213 is shared by GPCs 208 included in the PPU 202. In a cache hierarchy, the L3 cache 213 is positioned further upstream from streaming multiprocessors (SMs) executing threads than level one (L1) and level two (L2) caches included in the PPU 202. In some examples, such as in the illustrated example of FIG. 2, the L3 cache 213 is the highest level cache (HLC) in a cache hierarchy. In some examples, the PPU 202 and/or the parallel processing subsystem 112 includes one or more additional levels of cache (e.g., level four (L4) cache, level five (L5) cache, etc.) that are positioned further upstream in a cache hierarchy. In some examples, the PPU does not include an L3 cache 213. In such examples, the L2 caches included in the PPU 202 are at the highest level of cache in the PPU 202 and/or the parallel processing subsystem 112.

The L3 cache 213 is coupled to a memory interface 214. The memory interface 214 includes a set of D of partition units 215, where D≥1. Each partition unit 215 is coupled to one or more dynamic random access memories (DRAMs) 220 residing within PP memory 204. In one embodiment, the number of partition units 215 equals the number of DRAMs 220, and/or each partition unit 215 is coupled to a different DRAM 220. In other embodiments, the number of partition units 215 can be different than the number of DRAMs 220. In some embodiments, one or more caches, such as L3 cache 213, can also be partitioned. For example, every L3 cache partition could handle read and write accesses for a specific address range. In such cases, a scope tree, discussed in greater detail below in conjunction with FIGS. 4-19, can be created for each address range.

Persons of ordinary skill in the art will appreciate that a DRAM 220 can be replaced with any other technically suitable storage device. In operation, various render targets, such as texture maps and/or frame buffers, can be stored across DRAMs 220, allowing partition units 215 to write portions of each render target in parallel to efficiently use the available bandwidth of PP memory 204.

A given GPC 208 can process data to be written to any of the DRAMs 220 within PP memory 204. Crossbar unit 210 is configured to route the output of each GPC 208 to the input of any partition unit 215 or to any other GPC 208 for further processing. GPCs 208 communicate with memory interface 214 via crossbar unit 210 to read from or write to various DRAMs 220. In one embodiment, crossbar unit 210 has a connection to I/O unit 205, in addition to a connection to PP memory 204 via memory interface 214, thereby enabling the processing cores within the different GPCs 208 to communicate with system memory 104 or other memory not local to PPU 202. In the embodiment of FIG. 2, crossbar unit 210 is directly connected with I/O unit 205. In various embodiments, crossbar unit 210 can use virtual channels to separate traffic streams between the GPCs 208 and/or partition units 215.

Again, GPCs 208 can be programmed to execute processing tasks relating to a wide variety of applications, including, without limitation, linear and/or nonlinear data transforms, filtering of video and/or audio data, modeling operations (e.g., applying laws of physics to determine position, velocity, and/or other attributes of objects), image rendering operations (e.g., tessellation shader, vertex shader, geometry shader, and/or pixel/fragment shader programs), general compute operations, etc. In operation, PPU 202 is configured to transfer data from system memory 104 and/or PP memory 204 to one or more on-chip memory units, process the data, and/or write result data back to system memory 104 and/or PP memory 204. The result data can then be accessed by other system components, including CPU 102, another PPU 202 within parallel processing subsystem 112, or another parallel processing subsystem 112 within computing system 100.

As noted herein, any number of PPUs 202 can be included in a parallel processing subsystem 112. For example, without limitation, multiple PPUs 202 can be provided on a single add-in card, or multiple add-in cards can be connected to communication path 113, or one or more of PPUs 202 can be integrated into a bridge chip. PPUs 202 in a multi-PPU system can be identical to or different from one another. For example, without limitation, different PPUs 202 might have different numbers of processing cores and/or different amounts of PP memory 204. In implementations where multiple PPUs 202 are present, those PPUs can be operated in parallel to process data at a higher throughput than is possible with a single PPU 202. Systems incorporating one or more PPUs 202 can be implemented in a variety of configurations and/or form factors, including, without limitation, desktops, laptops, handheld personal computers or other handheld devices, servers, workstations, game consoles, embedded systems, and/or the like.

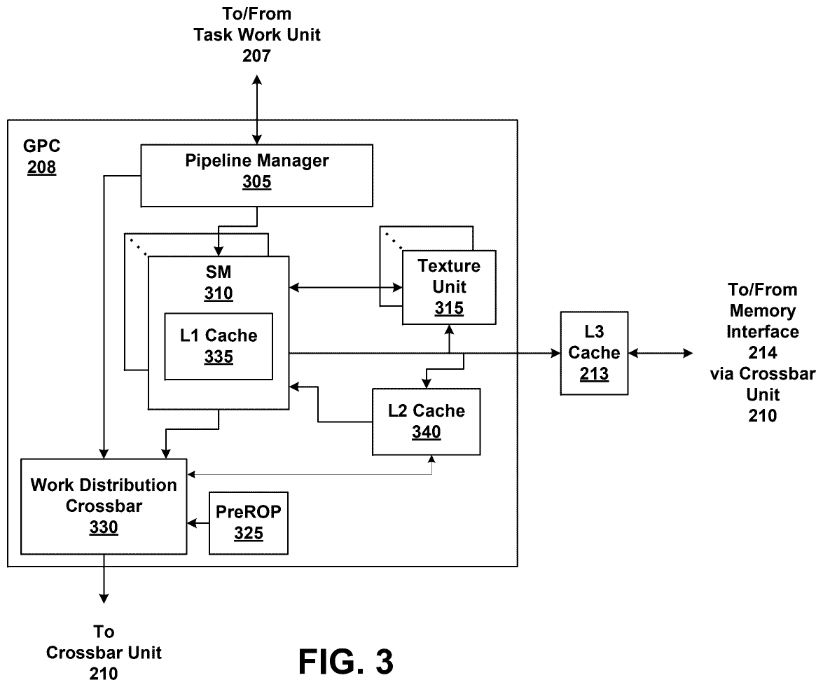

FIG. 3 is a block diagram of a general processing cluster (GPC) 208 included in the parallel processing unit (PPU) 202 of FIG. 2, according to various embodiments. In operation, GPC 208 can be configured to execute a large number of threads in parallel to perform graphics, general processing and/or compute operations. As used herein, a “thread” refers to an instance of a particular program executing on a particular set of input data. In some embodiments, single-instruction, multiple-data (SIMD) instruction issue techniques are used to support parallel execution of a large number of threads without providing multiple independent instruction units. In other embodiments, single-instruction, multiple-thread (SIMT) techniques are used to support parallel execution of a large number of generally synchronized threads, using a common instruction unit configured to issue instructions to a set of processing engines within GPC 208. Unlike a SIMD execution regime, where all processing engines typically execute identical instructions, SIMT execution allows different threads to more readily follow divergent execution paths through a given program. Persons of ordinary skill in the art will understand that a SIMD processing regime represents a functional subset of a SIMT processing regime.

Operation of GPC 208 is controlled via a pipeline manager 305 that distributes processing tasks received from a work distribution unit (not shown) within task/work unit 207 to one or more streaming multiprocessors (SMs) 310. Pipeline manager 305 can also be configured to control a work distribution crossbar 330 by specifying destinations for processed data output by SMs 310.

In one embodiment, GPC 208 includes a set of Q SMs 310, where Q≥1. Also, each SM 310 includes a set of functional execution units (not shown), such as execution units and/or load-store units. Processing operations specific to any of the functional execution units can be pipelined, which enables a new instruction to be issued for execution before a previous instruction has completed execution. Any combination of functional execution units within a given SM 310 can be provided. In various embodiments, the functional execution units can be configured to support a variety of different operations including integer and/or floating point arithmetic (e.g., addition and/or multiplication), comparison operations, Boolean operations (e.g., AND, OR, XOR), bit-shifting, and/or computation of various algebraic functions (e.g., planar interpolation and/or trigonometric, exponential, and/or logarithmic functions, etc.). Advantageously, the same functional execution unit can be configured to perform different operations.

In operation, each SM 310 is configured to process one or more thread groups. As used herein, a “thread group” or “warp” refers to a group of threads concurrently executing the same program on different input data, with one thread of the group being assigned to a different execution unit within an SM 310. A thread group can include fewer threads than the number of execution units within the SM 310, in which case some of the execution can be idle during cycles when that thread group is being processed. A thread group can also include more threads than the number of execution units within the SM 310, in which case processing can occur over consecutive clock cycles and/or across multiple SMs 310. Since each SM 310 can support up to G thread groups concurrently, it follows that up to G*Q thread groups can be executing in GPC 208 at any given time.

### Vertical Multi-Function Power Delivery Devices

FIG. 4 is a schematic diagram illustrating a power delivery device 400, according to various embodiments. Power delivery devices are also sometimes referred to as “power delivery modules” or “power modules.” As shown, the power delivery device 400 includes an inductor 420 on top of which two DrMOS (driver plus MOSFET (metal-oxide-semiconductor field-effect transistor)) modules 404 and 406 are mounted, a pillar or plating 408, and pillars or plating 410i (referred to herein individually as a pillar or plating 410 and collectively as pillars or plating 410). Illustratively, the power delivery device 400 is mounted on top of a circuit board 420. For example, in some embodiments, the circuit board 420 can be a motherboard, the main board of a graphics card, or the like. The power delivery device 400 can be mounted on top of the circuit board 420 in any technically feasible manner, such as via surface mount soldering (SMT) using tin.

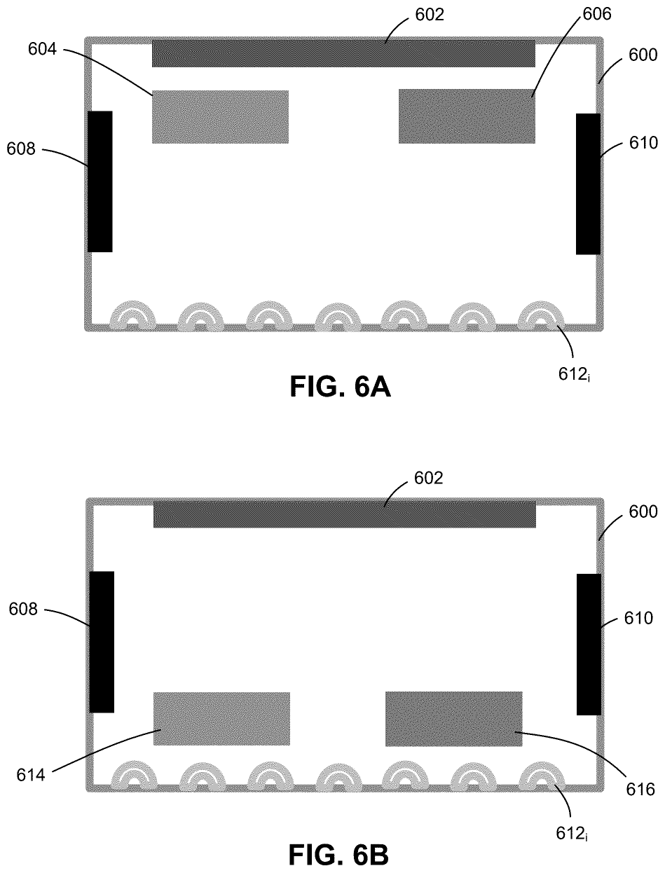

In operation, the DrMOS modules 404 and 406 generate, from a power supply, core voltage for a processor (not shown) mounted on top of another side of the circuit board 420. In some embodiments, each of the DrMOS modules 404 and 406 is an integrated circuit (also referred to herein as a “chip”). In some embodiments, the DrMOS modules 404 and 406 can control the current flow from the power supply to the processor while maintaining a relatively stable voltage output. Any technically feasible DrMOS modules, including well known DrMOS modules, can be used in some embodiments. Although described herein primarily with respect to DrMOS modules as a reference example, in some embodiments, any technically feasible chip that generates voltage from a power supply can be used. In some embodiments, each of the DrMOS modules 404 and 406 is mounted (e.g., via SMT using tin) on top of a footprint, such as a copper plating footprint, that is in a body of the inductor 420. Among other things, the footprint includes the pillar or plating 408 in two sides of the power delivery device 400 that are used to transfer power to the DrMOS modules 404 and 406, as well as the pillars or plating 410 in two other sides of the power delivery device 400 that are used to transfer signals to the DrMOS modules 404 and 406. Example footprints are discussed in greater detail below in conjunction with FIGS. 6A-6B, 7A-7B, 8, and 9. Each of the DrMOS modules 404 and 406 can include a matching footprint that is mounted on a footprint in the body of the inductor 420.

In operation, the inductor 420 smooths out voltage delivered to the processor by filtering out high frequency noise with an output capacitor combination. In some embodiments, the inductor 420 also acts as an interposer to connect signals between the circuit board 420 and the DrMOS modules 404 and 406. That is, the inductor 420 is a multi-function inductor that acts as a connection interposer as well as an inductor. In some embodiments, the inductor 420 can be constructed from an alloy of composite metals, such as iron powder mixed with one or more other materials. For example, in some embodiments, the inductor 420 can be constructed from FeSi or FeSiAl.

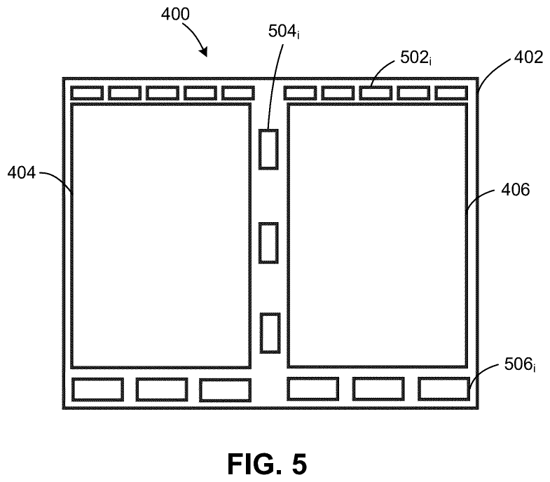

FIG. 5 is a schematic diagram illustrating a top-down view of the power delivery device 400 of FIG. 4, according to various embodiments. As shown, the power delivery device 400 includes the DrMOS modules 404 and 406 that are mounted on top of the inductor 402. The power delivery device 400 also includes resistors 502i (referred to herein individually as a resistor 502 and collectively as resistors 502, as peripheral for DrMOS modules 404 and 406) and capacitors 504i (referred to herein individually as a capacitor 504 and collectively as capacitors 504), as well as capacitors 506i (referred to herein individually as a capacitor 506 and collectively as capacitors 506). In operation, the capacitors 504 and 506 provide coupling for inputs to the DrMOS modules 404 and 406, and the capacitors 504 and 506 can store and release energy to help maintain a stable input voltage supply to the DrMOS modules 404 and 406. Advantageously, the inductor 402 itself is used to combine the DrMOS module 404 and 406, the inductor 402, the resistors 502, and the capacitors 504 and 506 into the power delivery device 400, which can result in a simplified and smaller power delivery device relative to convention power modules that require other discrete components, such as printed circuit boards (PCBs) and connectors, to combine DrMOS modules with inductors, resistors, and capacitors.

FIG. 6A is a schematic diagram illustrating a top-down view of an inductor 600, according to various embodiments. In some embodiments, the inductor 600 can correspond to the inductor 402, described above in conjunction with FIG. 4. As shown, a body of the inductor 600 includes input voltage (Vin) footprints 604 and 606 that can link to different DrMOS modules (e.g., DrMOS modules 404 and 406); pillars or plating 602, 608, and 610 extending from a top to a bottom of the inductor 600; and pillars or plating 612i (referred to herein individually as a pillar or plating 612 and collectively as pillars or plating 612) extending from the top to the bottom of the inductor 600. It should be understood that the Vin footprints 604 and 606; the pillars or plating 602, 608, and 610, and the pillars or plating 612 are different footprints in the body of the inductor 600. The pillars or plating 602, 608, and 610 can be used to transfer power to the DrMOS modules. In some embodiments, the pillar or plating 602 can be used for switch nodes (SW), and the pillar or plating 602 can also link two DrMOS modules together. In some embodiments, the pillars or plating 608 and 610 can be used for ground. In some embodiments, the pillars or plating 612 can be used to transfer signals to the DrMOS modules. For example, in some embodiments, the pillars or platings 612 can include the following signal pins: 1×EN, 2×PWM (pulse width modulation), 2×Imon, 1×VCC (voltage common collector), 1×Tmon. In some embodiments, the pillars or plating 612 can correspond to the pillars or plating 410, and the pillar or plating 610 can correspond to the pillar or plating 408, described above in conjunction with FIG. 4. In some embodiments, a plating technique can be used to create the pillars or plating 602, 608, 610, and 612 in the body of the inductor 600.

FIG. 6B is a schematic diagram illustrating a bottom-up view of the inductor 600 of FIG. 6A, according to various embodiments. As shown, a body of the inductor 600 also includes output voltage (Vout) footprints 614 and 616, which source voltage to a processor, such as a GPU. Within the body of the inductor 600, coils (not shown) can connect the Vin footprints 604 and 606 to the Vout footprints 614 and 616, respectively.

The bottom of the inductor 600 can be mounted on top of a circuit board, such as the circuit board 420 described above in conjunction with FIG. 4. The pillars or plating 602, 608, 610, and 612 extend from the circuit board to the DrMOS modules (e.g., DrMOS modules 404 and 406) mounted on top of the inductor 600, which are linked by the body of the inductor 600.

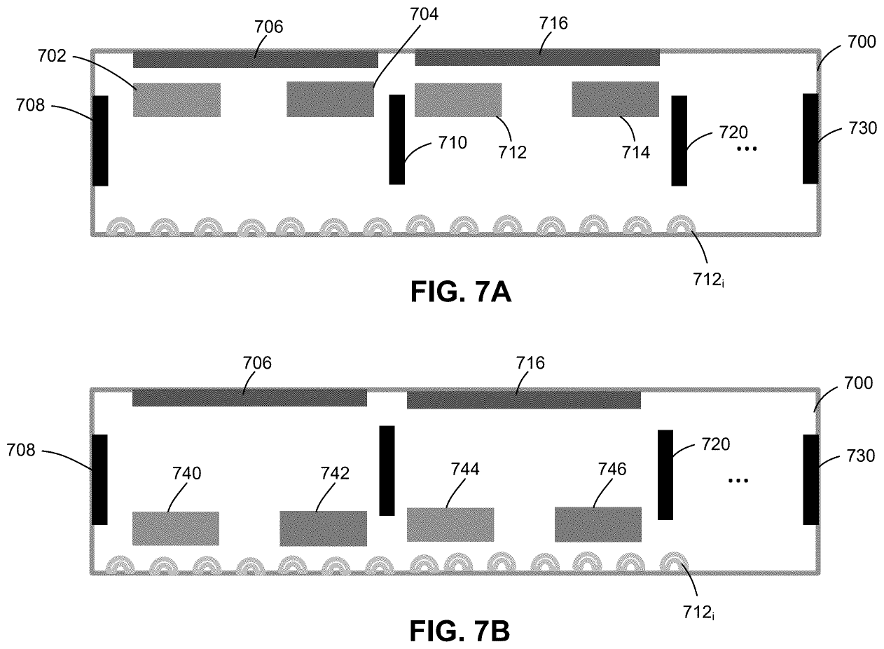

FIG. 7 is a schematic diagram illustrating a top-down view of an inductor 700, according to various other embodiments. As shown, in a body of the inductor 700 are footprints 702, 704, 712, and 714, on top of which DrMOS modules can be mounted; pillars or plating 706, 708, 710, 716, 720, and 730 extending from a top to a bottom of the inductor 700; and pillars or plating 712i (referred to herein individually as a pillar or plating 712 and collectively as pillars or plating 712) extending from the top to the bottom of the inductor 700. The inductor 700 is similar to the inductor 600, described above in conjunction with FIG. 6, except the inductor 700 includes footprints that permit more than two DrMOS modules to be mounted on top of the inductor 700. More generally, in some embodiments, any number of DrMOS modules can be mounted on top of an inductor, depending on the number of power phases that are desired. For example, in some embodiments, more than one DrMOS module can be mounted on top of an inductor to save size. The pillars or plating 706, 708, 710, 716, 720, and 730 can be used to transfer power to DrMOS modules (not shown), similar to the pillars or plating 602, 608, and 610, described above in conjunction with FIG. 6, except repeating a number of times. The pillars or plating 712 can be used to transfer signals to the DrMOS modules. In some embodiments, the pillars or plating 712 can include the same signal pins as the pillars or plating 612, described above in conjunction with FIG. 6A, except the same signal pins repeat a number of times. In some embodiments, a plating technique can be used to create the pillars or plating 602, 608, 610, and 612 in the body of the inductor 600.

FIG. 7B is a schematic diagram illustrating a bottom-up view of the inductor 700 of FIG. 7A, according to various embodiments. As shown, a body of the inductor 700 also includes Vout footprints 740, 742, 744, and 746. The Vout footprints 740, 742, 744, and 746 are similar to the Vout footprints 614 and 616, described above in conjunction with FIG. 6B, except the Vout footprints 614 and 616 are repeated a number of times in the inductor 700. The bottom of the inductor 700 can be mounted on top of a circuit board, such as the circuit board 420 described above in conjunction with FIG. 4. The pillars or plating 706, 708, 710, 716, 720, and 730 extend from the circuit board to DrMOS modules mounted on top of the inductor 700, which are linked by the body of the inductor 700.

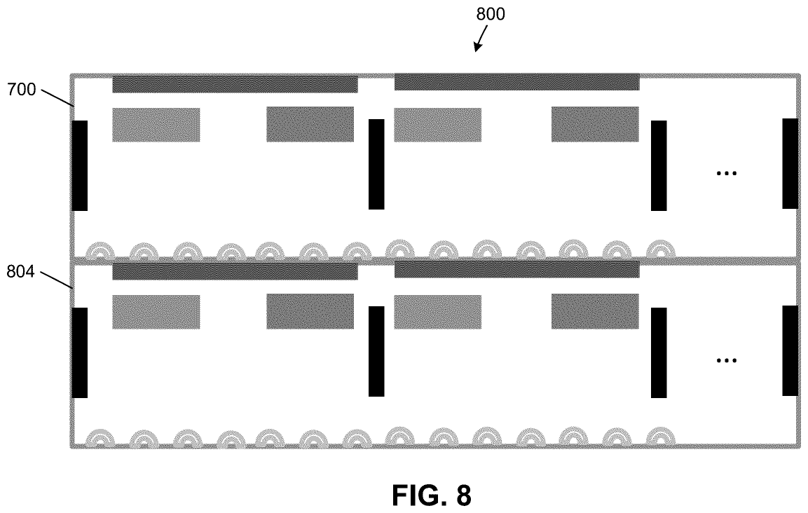

FIG. 8 is a schematic diagram illustrating a top-down view of a power delivery device 800, according to various other embodiments. As shown, the power delivery device 800 includes the inductor 700, described above in conjunction with FIG. 7, and an inductor 800 that is similar to the inductor 700. As illustrated in FIGS. 7 and 8, a power delivery device that includes an inductor on top of which DrMOS modules are mounted can be extended any number of times in the X and/or Y directions of a plane parallel to a circuit board, depending on the number of power phases that are desired.

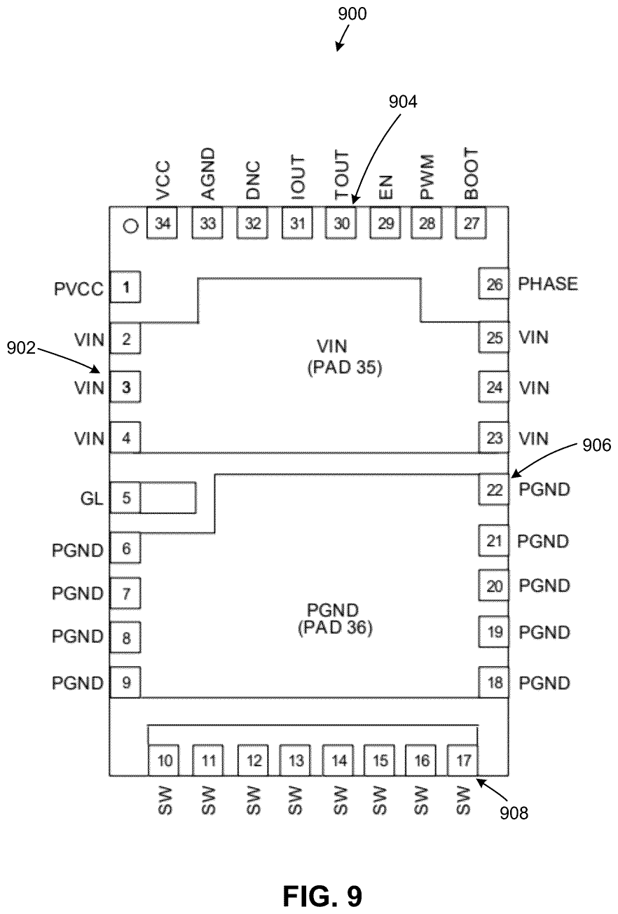

FIG. 9 is a schematic diagram illustrating an exemplar footprint 900 on top of which a DrMOS can be mounted on an inductor, according to various embodiments. As shown, the footprint 900 includes pins 902 for Vin into a DrMOS (not shown); various pins 904 for, e.g., temperature monitor output (TOUT) to protect the DrMOS from overheating, among other things; pins 908 for the DrMOS phase output to the inductor; and pins 906 for ground.

Illustratively, the pins 902 include Vin pins, which can correspond to pins in the Vin footprints 604 or 606, described above in conjunction with FIG. 6A, in some embodiments. The pins 904 include signal pins, which can correspond to the signal pins 612, described above in conjunction with FIG. 6A, in some embodiments. The pins 906 include ground pins, which can correspond to the pillars or plating 608 and 610 for ground, described above in conjunction with FIG. 6A, in some embodiments. The pins 908 include switch nodes (SW), which can correspond to the pillar or plating 602 for switch nodes, described above in conjunction with FIG. 6A, in some embodiments. The pins 902, 904, 906, and 908 can be constructed from any technically feasible material, such as copper, in some embodiments. Although a particular footprint 900 is shown for illustrative purposes, in some embodiments any suitable footprint can be used.

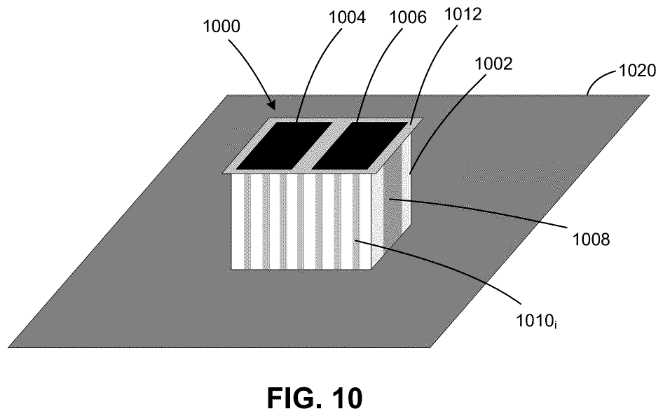

FIG. 10 is a schematic diagram illustrating a power delivery device 1000, according to various other embodiments. As shown, the power delivery device 1000 includes an inductor 1002, two DrMOS modules 1004 and 1006, an interposer 1012 between the DrMOS modules 1004 and 1006 and the inductor 1002, a pillar or plating 1008, and pillars or plating 1010i (referred to herein individually as a pillar or plating 1010 and collectively as pillars or plating 1010). The power delivery device 1000 is mounted on top of a circuit board 1020 via, e.g., SMT. The inductor 1002, the DrMOS modules 1004 and 1006, the pillar or plating 1008, the pillars or plating 1010, and the circuit board 1020 are similar to the inductor 402, the DrMOS modules 404 and 406, the pillar or plating 408, the pillars or plating 410, and the circuit board 420, respectively, described above in conjunction with FIG. 4. However, the power delivery device 1000 includes the interposer 1012 between the DrMOS modules 1004 and 1006 and the inductor 1002, as opposed to the DrMOS modules 1004 and 1006 being directly mounted on top of the inductor 1002. In some embodiments, the interposer 1012 can be a PCB mounted on top of a body of the inductor 1002, and the DrMOS modules 1004 and 1006 are mounted on top of the interposer 1012. In such cases, the interposer 1012 can be used, along with the inductor 1002, to connect signals between the circuit board 1020 and the DrMOS modules 404 and 406.

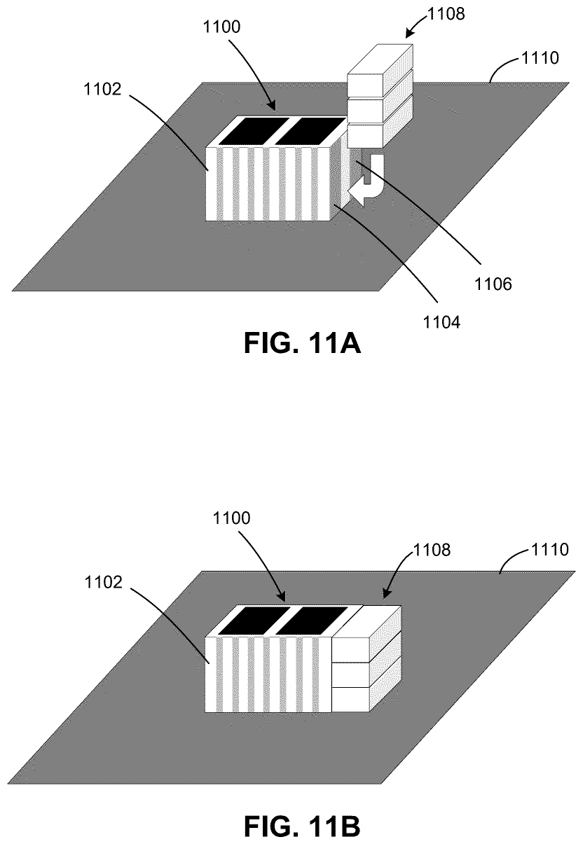

FIGS. 11A and 11B are schematic diagrams illustrating a power delivery device 1100, according to various other embodiments. As shown in FIG. 11A, the power delivery device 1100 includes an inductor 1102, on top of which two DrMOS modules are mounted. The power delivery device 1100 also includes a stack of capacitors 1108 that are mounted on one side of the inductor 1108 using, e.g., SMT, as shown in FIG. 11B. In some embodiments, the stack of capacitors 1104 can include a footprint that is mounted (e.g., soldered) together with a footprint that includes a pillar or plating 1106 for output and a pillar or plating 1106 for ground on a side of the inductor 1102. Although the stack of capacitors 1108 are shown on one side of the inductor 1108 for illustrative purposes, in some embodiments, stacks of capacitors can be mounted around an inductor on one or more sides, including around all sides of the inductor. The inductor 1102 is similar to the inductor 402, described above in conjunction with FIG. 4, except the stack of capacitors 1108 are mounted on one side of the inductor 1102 to act as output capacitors for buck DC-DC conversion.

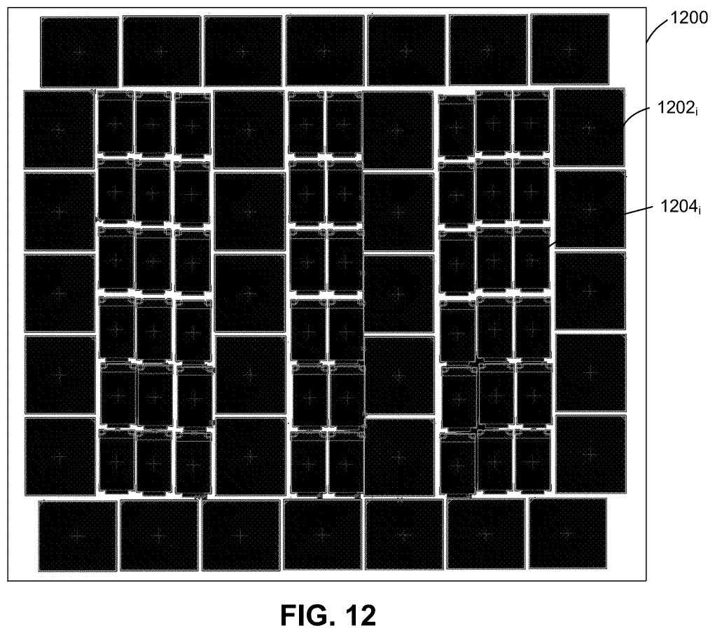

FIG. 12 is a schematic diagram illustrating a bottom-up view of a GPU 1200 and associated power delivery devices, according to various embodiments. As shown, a number of power delivery devices 1202i (referred to herein individually as a power delivery device 1202 and collectively as power delivery devices 1202) can be used to deliver power to the GPU 1200 from the bottom, i.e., provide a vertical supply of power to the GPU 1200. Also shown are a number of output capacitors 1204i (referred to herein individually as an output capacitor 1204 and collectively as output capacitors 1204). In some embodiments, each of the power delivery devices 1202 can be one of the power delivery devices 400, 600, 700, 800, 1000, or 1100, described above in conjunction with FIGS. 4, 6, 7, 8, 10, and 11, respectively. In some embodiments, the power delivery devices 1202 and the output capacitors 1204 can be mounted via, e.g., SMT on top of a circuit board on a different side than the GPU 1200 is mounted on top of, as described above in conjunction with FIG. 4.

In sum, vertical multi-function power delivery devices are disclosed. In some embodiments, a power delivery device includes one or more DrMOS modules mounted on top of an inductor. The DrMOS module(s) can be directly mounted on top of a footprint on the inductor, and the inductor can include footprints on the top and bottom sides of the inductor body as well as plating and/or pillars that extend from the top to the bottom of the inductor. The plating and/or pillars are used to transmit power and signals to the DrMOS module(s). Alternatively, the DrMOS module(s) can be mounted on top of an interposer, such as a PCB, that is mounted on top of the inductor. In some embodiments, the power delivery device can also include one or more capacitors on one or more sides, such as all sides, of the inductor.

One technical advantage of the disclosed techniques relative to the prior art is that the disclosed power delivery devices can be smaller in size (in the x-y plane and in height) relative to the power phases used in conventional power delivery approaches. Accordingly, a relatively large number of the disclosed power delivery devices can be placed underneath a processor to deliver power, which permits a higher amount of power to be delivered. In addition, the disclosed power delivery devices can provide improved power supply efficiency, including higher power density, relative to conventional power delivery approaches. These technical advantages provide one or more technological improvements over prior art approaches.
1. In some embodiments, a power delivery device comprises an inductor, and one or more chips that are mounted on top of the inductor.
2. The power delivery device of clause 1, wherein the one or more chips are mounted on top of one or more footprints disposed in the inductor.
3. The power delivery device of clauses 1 or 2, wherein each footprint included in the one or more footprints comprises at least one of an input pin, an output pin, or a ground pin.
4. The power delivery device of any of clauses 1-3, further comprising at least one or more platings or one or more pillars that are disposed in one or more sides of the inductor.
5. The power delivery device of any of clauses 1-4, wherein the at least one or more platings or one or more pillars transmit at least one of power or one or more signals to the one or more chips.
6. The power delivery device of any of clauses 1-5, further comprising one or more capacitors that are mounted on one or more sides of the inductor.
7. The power delivery device of any of clauses 1-6, wherein each chip included in the one or more chips comprises a driver plus metal-oxide-semiconductor field-effect transistor.
8. The power delivery device of any of clauses 1-7, further comprising at least one or more resistors or one or more capacitors mounted on top of the inductor.
9. The power delivery device of any of clauses 1-8, wherein the one or more chips are mounted on top of an interposer that is mounted on top of the inductor.
10. The power delivery device of any of clauses 1-9, wherein the power delivery device is mounted on a first side of a circuit board, and a processor is mounted on a second side of the circuit board.
11. In some embodiments, a graphics card comprises a circuit board, a graphics processing unit (GPU) mounted on top of a first side of the circuit board, and one or more power delivery devices mounted on top of a second side of the circuit board, wherein each power delivery device included in the one or more power delivery devices comprises an inductor and one or more chips disposed on top of the inductor.
12. The graphics card of clause 11, wherein the one or more chips are mounted on top of the inductor.
13. The graphics card of clauses 11 or 12, wherein the one or more chips are mounted on top of one or more footprints disposed in the inductor.
14. The graphics card of any of clauses 11-13, wherein the one or more chips are mounted on top of an interposer, and the interposer is mounted on top of the inductor.
15. The graphics card of any of clauses 11-14, wherein the interposer comprises a printed circuit board (PCB).
16. The graphics card of any of clauses 11-15, wherein each power delivery device included in the one or more power delivery devices further comprises at least one or more platings or one or more pillars disposed in one or more sides of the inductor included in the power delivery device.
17. The graphics card of any of clauses 11-16, wherein the at least one or more platings or one or more pillars are configured to transmit at least one of power or one or more signals to the GPU.
18. The graphics card of any of clauses 11-17, wherein each power delivery device included in the one or more power delivery devices further comprises one or more capacitors mounted on one or more sides of the inductor included in the power delivery device.
19. The graphics card of any of clauses 11-18, wherein each chip included in the one or more chips comprises a driver plus metal-oxide-semiconductor field-effect transistor.
20. In some embodiments, a computer system comprises a processor, and one or more power delivery devices that delivery power to the processor, wherein each power delivery device included in the one or more power delivery devices comprises an inductor on top of which one or more chips are mounted.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and/or variations will be apparent to those of ordinary skill in the art without departing from the scope and/or spirit of the described embodiments.

Aspects of the present embodiments can be embodied as a system, method, or computer program product. Accordingly, aspects of the present disclosure can take the form of an entirely hardware embodiment, an entirely software embodiment (including firmware, resident software, micro-code, etc.) or an embodiment combining software and/or hardware aspects that can all generally be referred to herein as a “module” or “system.” Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described herein with reference to flowchart illustrations and/or block diagrams of methods, apparatus (systems) and/or computer program products according to embodiments of the disclosure. It will be understood that each block of the flowchart illustrations and/or block diagrams, and/or combinations of blocks in the flowchart illustrations and/or block diagrams, can be implemented by computer program instructions. These computer program instructions can be provided to a processor of a general purpose computer, special purpose computer, or other programmable data processing apparatus to produce a machine, such that the instructions, which execute via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowcharts and/or block diagrams in the figures illustrate the architecture, functionality, and/or operation of possible implementations of systems, methods, and/or computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that perform the specified functions or acts, or combinations of special purpose hardware and/or computer instructions.

While the preceding is directed to embodiments of the present disclosure, other and/or further embodiments of the disclosure can be devised without departing from the basic scope thereof, and/or the scope thereof is determined by the claims that follow.

What is claimed is:

1. A power delivery device, comprising:
an inductor; and
one or more chips that are mounted on top of the inductor.

2. The power delivery device of claim 1, wherein the one or more chips are mounted on top of one or more footprints disposed in the inductor.

3. The power delivery device of claim 2, wherein each footprint included in the one or more footprints comprises at least one of an input pin, an output pin, or a ground pin.

4. The power delivery device of claim 1, further comprising at least one or more platings or one or more pillars that are disposed in one or more sides of the inductor.

5. The power delivery device of claim 4, wherein the at least one or more platings or one or more pillars transmit at least one of power or one or more signals to the one or more chips.

6. The power delivery device of claim 1, further comprising one or more capacitors that are mounted on one or more sides of the inductor.

7. The power delivery device of claim 1, wherein each chip included in the one or more chips comprises a driver plus metal-oxide-semiconductor field-effect transistor.

8. The power delivery device of claim 1, further comprising at least one or more resistors or one or more capacitors mounted on top of the inductor.

9. The power delivery device of claim 1, wherein the one or more chips are mounted on top of an interposer that is mounted on top of the inductor.

10. The power delivery device of claim 1, wherein the power delivery device is mounted on a first side of a circuit board, and a processor is mounted on a second side of the circuit board.

11. A graphics card, comprising:
a circuit board;
a graphics processing unit (GPU) mounted on top of a first side of the circuit board; and
one or more power delivery devices mounted on top of a second side of the circuit board,
wherein each power delivery device included in the one or more power delivery devices comprises an inductor and one or more chips disposed on top of the inductor.

12. The graphics card of claim 11, wherein the one or more chips are mounted on top of the inductor.

13. The graphics card of claim 11, wherein the one or more chips are mounted on top of one or more footprints disposed in the inductor.

14. The graphics card of claim 11, wherein the one or more chips are mounted on top of an interposer, and the interposer is mounted on top of the inductor.

15. The graphics card of claim 14, wherein the interposer comprises a printed circuit board (PCB).

16. The graphics card of claim 11, wherein each power delivery device included in the one or more power delivery devices further comprises at least one or more platings or one or more pillars disposed in one or more sides of the inductor included in the power delivery device.

17. The graphics card of claim 16, wherein the at least one or more platings or one or more pillars are configured to transmit at least one of power or one or more signals to the GPU.

18. The graphics card of claim 11, wherein each power delivery device included in the one or more power delivery devices further comprises one or more capacitors mounted on one or more sides of the inductor included in the power delivery device.

19. The graphics card of claim 11, wherein each chip included in the one or more chips comprises a driver plus metal-oxide-semiconductor field-effect transistor.

20. A computer system, comprising:
a processor; and
one or more power delivery devices that delivery power to the processor, wherein each power delivery device included in the one or more power delivery devices comprises an inductor on top of which one or more chips are mounted.
